(19) United States
(12) Patent Application Publication
(10) Pub. No.: US 2018/0212562 A1
(43) Pub. Date: Jul. 26, 2018

(54) OPTICAL CONCENTRATION SYSTEM FOR A SOLAR ENERGY ASSEMBLY

(71) Applicant: Saint-Augustin Canada Electric Inc., Saint-Augustin de Desmaures (CA)

(72) Inventors: Sascha Van Riesen, Freiburg (DE); Martin Neubauer, Freiburg (DE); Andreas Gombert, Freiburg (DE)

(21) Appl. No.: 15/745,376

(22) PCT Filed: Jul. 11, 2016
(86) PCT No.: PCT/CA2016/050808

§ 371 Date: Jan. 16, 2018

(30) Foreign Application Priority Data
Jul. 16, 2015 (DE) 102015213395.8

(51) Int. Cl. H02S 40/22; H01L 31/054

(52) U.S. Cl. CPC H02S 40/22; H01L 31/0547; H01L 31/0543

(57) ABSTRACT

An optical concentration system for a solar energy assembly, in particular, for a concentrator solar energy assembly, for concentrating incoming light onto a target area such as a solar cell in the solar energy assembly, includes a first optical element for collecting the incoming light and forming a light cone toward the target area, and a second optical element adjacent to the target area. In order to provide an optical concentration system for a solar energy assembly, which allows a high efficiency for light transmission and concentration and which is easy to manufacture, the first optical element is a multi-focal element and that the second optical element is adapted to reflect the light to at least one region of the target area that is outside the center of the target area.

### CROSS-REFERENCE TO RELATED APPLICATIONS

This application is a national phase entry under 35 U.S.C. § 371 of International Patent Application PCT/CA2016/050808, filed Jul. 11, 2016, designating the United States of America and published in English as International Patent Publication WO 2017/008152 A1 on Jan. 19, 2017, which claims the benefit under Article 8 of the Patent Cooperation Treaty to German Patent Application Ser. No. 102015213395.8, filed Jul. 16, 2015.

### TECHNICAL FIELD

The present disclosure is directed to an optical concentration system and a concentrator solar energy assembly.

BACKGROUND

Optical concentration systems and concentrator solar energy assemblies are known in the prior art. They can be used to concentrate sunlight onto target areas. In the target areas, highly efficient photovoltaic elements such as solar cells or solar thermal absorber elements can be placed. In the concentration systems as known in the prior art, optical systems are used that are either expensive, laborious to manufacture, lose efficiency due to strongly inhomogeneous illumination, or lose a large portion of the light due to absorption and/or reflection and, therefore, are inefficient.

### BRIEF SUMMARY

It is, therefore, an object of the present disclosure to provide an optical concentration system and a concentrator solar energy assembly that is easy to produce and that provides a high yield of concentrated light as well as homogenizes the illumination on the target, i.e., the photovoltaic element.

The solution according to the disclosure, allows at least a part of the light that is directed from the first optical element toward the target area to reach the target area unobstructed. Therefore, the optical concentration system can provide a highly efficient system for transporting light to the target area. The term “light cone,” as used herein, refers to the shape of the light beam after passing the first optical element. Since the first optical element concentrates the incoming light, the resulting light beam tapers toward the target area. The boundaries of the light beam may be shaped as a cone, at least in the space close to the target. It may be noted that, if the first optical element has a square aperture, the light beam may be shaped pyramidal at least in the space close to the first optical element. For the sake of convenience, the light that is directed from the first optical element toward the target area is termed “light cone” in the following disclosure.

The light that is directed from the first optical element toward the target area is homogenized, because the first optical element is a multi-focal element.

The second optical element reflects light to a region of the target area that is outside the center of the target area or to a border region of the target area. It may, therefore, serve as a second homogenizer. The light that is concentrated from the first optical element toward the target area generally has a distribution in which the intensity of the light is the highest in the center of the target area. When the reflected light then superimposes with the light outside the center of the target area, the resulting distribution gets homogenized.

To summarize, the first optical element and the second optical element, which each serve as homogenizers, form a double homogenizing system. This solution leads to a homogeneous illumination of the target area and, at the same time, a negligible loss of light, especially compared to a system that uses a point focus created by the first optical element.

Further, advantageous improvements are described in the dependent claims.

Further advantageous improvements will be described in the following disclosure. The improvements described herein may be combined independently of each other, depending on whether a particular advantage of a particular improvement is needed in a specific application.

According to a first advantageous improvement, the first optical element may be adapted to irradiate an area that exceeds the target area. In this case, it is ensured that the whole target area is illuminated. The portion of light that exceeds the target area can be directed by the second optical element toward the target area. In this case, the majority of the light that is part of the light cone reaches the target area.

In a preferred embodiment, the first optical element is a refractive element, such as a Fresnel lens, in particular, a color-mixing Fresnel lens. However, the disclosure is not restricted to a Fresnel lens. Any other suitable multi-focal optical element may be used. For example, the first optical element may be a total internal reflection element or a mirror.

According to another advantageous embodiment, the first optical element may have a surface with an overall planar shape. The first optical element may be part of an array, for example, a Fresnel lens array.

In order to reflect the majority of light that exceeds the target area, the second optical element may completely surround the target area. It may also be possible that the second optical element only partially surrounds the target area. The second optical element may taper toward the target area and/or may be funnel-shaped.

In the following, embodiments of the invention and its improvements are described in greater detail using an exemplary embodiment and with reference to the figures. As described above, the various features shown in the embodiment may be used independently of each other in specific applications.

### BRIEF DESCRIPTION OF THE DRAWINGS

In the following figures, elements having the same function and/or the same structure will be referenced by the same reference signs. In the drawings:

FIG. 1 shows a schematic cross-sectional view of a concentrator solar energy assembly with an optical concentration system according to the disclosure;

FIG. 2 schematically shows a light distribution achieved by the optical concentration system as shown in FIG. 1.

### DETAILED DESCRIPTION

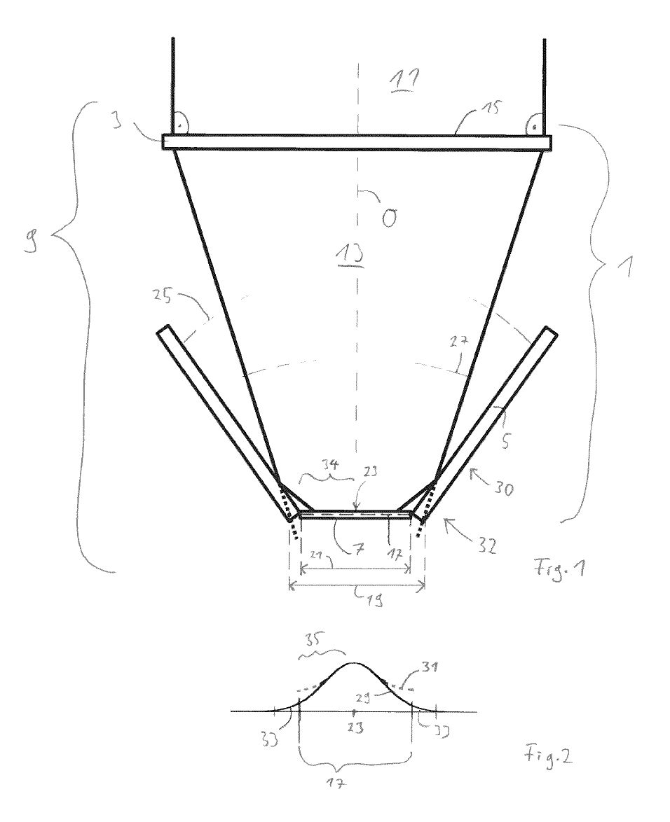

FIG. 1 shows an optical concentration system 1 comprising a first optical element 3 and a second optical element 5. The optical concentration system 1 forms together with a photovoltaic element (solar cell 7) and a concentrator solar energy assembly 9.

In the following, the optical concentration system 1 and the concentrator solar energy assembly 9 are described in an order that follows the path of light that illuminates the optical concentration system 1 along an optical axis O. Incoming light 11 illuminates the first optical element 3. The incoming light 11 is, in general, sunlight, and can, therefore, be seen as a bunch of parallel light rays. Preferably, the first optical element 3 is arranged in a way that the incoming light 11 illuminates it with a normal incidence. This is indicated in FIG. 1 with the right angles. In order to keep a normal incidence, a concentrator solar energy assembly 9 can be provided with an auto-tracking system (not shown) following the relative movement of the sun.

The first optical element 3 is adapted to at least partially focus the incoming light 11 in a way that a light cone 13 or a light beam shaped as a truncated pyramid is formed. The first optical element 3 is shown schematically with a rectangular cross-section. It may have any applicable shape. However, it is preferred that at least the outer surface 15 of the first optical element 3 has an overall planar shape. The planar shape may facilitate cleaning of the first optical element 3 and may allow a compact structural form, especially if several optical concentration systems 1 are combined in order to form an array.

The first optical element 3 may be or include a Fresnel lens. However, other optical elements may also be used, for example, an element that uses total internal reflection. More preferably, the first optical element 3 is or includes a color-mixing multi-focal Fresnel lens.

The light cone 13 illuminates the target area 17, which is shown as a dashed line in FIG. 1. A solar cell 7 or a solar thermal element may be placed in the target area 17. If a second optical element 5 was not present, the light cone 13 would illuminate an area with at least a width 19 in the shown cross-section, which is larger than the width 29 of the target area 17. Preferably, the largest portion of the light cone 13 reaches the target area 17 unobstructed.

Adjacent to the target area 17, the second optical element 5 is placed. The second optical element 5 preferably completely surrounds the target area 17 circumferentially around the optical axis O. Alternatively, the second optical element 5 may only partially surround the target area 17. The second optical element 5 is preferably shaped as the surface of a truncated cone or a truncated pyramid 30. It may taper toward the target area 17 and may surround the target area 17 with its smaller diameter end 32. The second optical element 5 preferably uses external reflection to reflect light toward the target area 17.

The second optical element 5 is adapted to especially reflect parts of the light cone 13 that would exceed the target area 17 if the second optical element 5 was not present. The second optical element 5 is arranged in a way that the light, which is reflected by it onto the target area 17, is preferably directed onto a region 34 of the target area 17 that is outside of the center 23 of the target area 17 and close to the borders of same. Benefits of this arrangement are described in further detail with respect to FIG. 2. In order to reflect the light as described, an opening angle 25 of the second optical element 5 may be larger than an opening angle 27 of the light cone 13.

FIG. 2 schematically shows a resulting light distribution 31 as achieved with the optical concentration system 1 as described with respect to FIG. 1. A light distribution 29 in the plane of the target area 17, which would result without the second optical element 5, is represented by the solid line. The light distribution 31 that results from the usage of the optical concentration system 1 that comprises a second optical element 5 is shown by the dashed line.

The shape of the light distribution 29 depends on the properties of the first optical element 3. The light distribution 29 can generally be described with a bell-shaped or a Gaussian-like function. In the center 23 of the target area 17, the light intensity has a maximum and it falls with increasing distance from the center 23. For comparison, the target area 17 is indicated in FIG. 2. Without a second optical element 5, the intensity rapidly decreases perpendicular to the optical axis O in the direction of the limits of the target area 17, and tails 33 of the distribution do not reach the target area 17 and, therefore, do not contribute to the collected light.

In contrast to this, the optical concentration system 1 with the second optical element 5 provides an advantageous light distribution 31. The tails 33 of the distribution 29 are reflected by the second optical element 5, mostly onto the region 34 of the target area 17. There, the light may superimpose with light of the distribution 29, which is presented by the region 35 of the distribution 29. The region 35 of the distribution 29 is the light that illuminates the region 34 of the target area 17 and is, therefore, the part of the distribution that is located between the maximum of the distribution 29 and the tails 33. The resulting light distribution 31 has two advantages over the light distribution 29:

First, the light distribution 31 is more homogenous since the decrease toward the limits of the target area 17 is lower than for the distribution 29. Second, the integral of the distribution 29 over the target area 17 and, therefore, the amount of collected light, is larger than for the distribution 29, since the tails 33 now also contribute to the collected light.

### REFERENCE NUMERALS

1 Optical concentration system

3 First optical element

5 Second optical element

7 Photovoltaic element

9 Concentrator solar energy assembly

11 Incoming light

13 Light cone

15 Outer surface

17 Target area

19 Width of the light cone

21 Width of the target area

23 Center of the target area

25 Opening angle of the second optical element

27 Opening angle of the light cone

29 Light distribution without second optical element

30 Truncated cone

31 Light distribution with second optical element

32 Smaller diameter end of truncated cone

33 Tails of the distribution

34 Region on the target area

35 Region of the light distribution

O Optical axis

1.-10. (canceled)

11. An optical concentration system for a concentrator solar energy assembly for concentrating incoming light onto a target area, the optical concentration system comprising:
a first optical element for collecting the incoming light and forming a light cone toward the target area; and
a second optical element adjacent to the target area;
wherein the second optical element leaves at least parts of the light cone from the first optical element to pass unobstructed to the target area;
wherein the first optical element is a multi-focal element; and
wherein the second optical element is adapted to reflect the light to at least one region of the target area that is outside the center of the target area.

12. The optical concentration system of claim 11, wherein the first optical element is a color-mixing Fresnel lens.

13. The optical concentration system of claim 12, wherein the at least one region of the target area is a border region of the target area.

14. The optical concentration system of claim 13, wherein the first optical element and the second optical element are arranged in such a way that light is distributed by the first optical element with a bell-shaped or a Gaussian-like distribution on the target area, wherein a portion of light represented by the tails of the bell-shaped distribution is reflected by the second optical element to superimpose on the target area with a portion of light represented by a region of the bell-shaped distribution between the maximum of the distribution and the tails.

15. The optical concentration system of claim 14, wherein the second optical element at least partially surrounds the target area.

16. The optical concentration system of claim 15, wherein the second optical element is adapted to use external reflection to reflect the light toward the target area.

17. The optical concentration system of claim 16, wherein the second optical element has an overall shape of the surface of a truncated cone with the smaller diameter end of the cone pointing toward the target area.

18. The optical concentration system of claim 17, wherein the truncated cone has an opening angle that is larger than an opening angle of the light cone.

19. The optical concentration system of claim 11, wherein the at least one region of the target area is a border region of the target area.

20. The optical concentration system of claim 11, wherein the first optical element and the second optical element are arranged in such a way that light is distributed by the first optical element with a bell-shaped or a Gaussian-like distribution on the target area, wherein a portion of light represented by the tails of the bell-shaped distribution is reflected by the second optical element to superimpose on the target area with a portion of light represented by a region of the bell-shaped distribution between the maximum of the distribution and the tails.

21. The optical concentration system of claim 11, wherein the second optical element at least partially surrounds the target area.

22. The optical concentration system of claim 11, wherein the second optical element is adapted to use external reflection to reflect the light toward the target area.

23. The optical concentration system of claim 11, wherein the second optical element has an overall shape of the surface of a truncated cone with the smaller diameter end of the cone pointing toward the target area.

24. A concentrator solar energy assembly including at least one solar cell and at least one optical concentration system for transmitting light to the solar cell, wherein the at least one optical concentration system comprises:
a first optical element for collecting incoming light and forming a light cone toward a target area; and
a second optical element adjacent to the target area;
wherein the second optical element leaves at least parts of the light cone from the first optical element to pass unobstructed to the target area;
wherein the first optical element is a multi-focal element; and
wherein the second optical element is adapted to reflect the light to at least one region of the target area that is outside the center of the target area.

25. The concentrator solar energy assembly of claim 24, wherein the second optical element is shaped as the surface of a truncated cone and wherein the solar cell is placed in the smaller diameter end of the truncated cone being surrounded by the same.

26. The concentrator solar energy assembly of claim 24, wherein the at least one region of the target area is a border region of the target area.

27. The concentrator solar energy assembly of claim 24, wherein the first optical element and the second optical element are arranged in such a way that light is distributed by the first optical element with a bell-shaped or a Gaussian-like distribution on the target area, wherein a portion of light represented by the tails of the bell-shaped distribution is reflected by the second optical element to superimpose on the target area with a portion of light represented by a region of the bell-shaped distribution between the maximum of the distribution and the tails.

28. The concentrator solar energy assembly of claim 24, wherein the second optical element at least partially surrounds the target area.

29. The concentrator solar energy assembly of claim 24, wherein the second optical element is adapted to use external reflection to reflect the light toward the target area.

30. The concentrator solar energy assembly of claim 24, wherein the second optical element has an overall shape of the surface of a truncated cone with the smaller diameter end of the cone pointing toward the target area.
